(19) United States
(12) Patent Application Publication
(10) Pub. No.: US 2026/0089829 A1
(43) Pub. Date: Mar. 26, 2026

(54) ION IMPLANTER, CONTROL SYSTEM, AND TECHNIQUES FOR TUNING BUNCHER OF ION IMPLANTER

(71) Applicant: Applied Materials, Inc., Santa Clara, CA (US)

(72) Inventors: Maximilian Schneider, Boston, MA (US); William Herron Park, JR., Marblehead, MA (US); Wai Ming Tam, Georgetown, MA (US); Peter F. Kurunczi, Cambridge, MA (US); Frank Sinclair, Hartland, ME (US); Christopher Ilic Lang, Boston, MA (US)

(73) Assignee: Applied Materials, Inc., Santa Clara, CA (US)

(21) Appl. No.: 18/895,964

(22) Filed: Sep. 25, 2024

(51) Int. Cl. H05H 7/04; H01J 37/08; H01J 37/317; H05H 11/00

(52) U.S. Cl. CPC H05H 7/04; H01J 37/08; H01J 37/3171; H05H 11/00; H01J 2237/0473; H01J 2237/24564; H05H 2007/041; H05H 2277/12

(57) ABSTRACT

An ion implanter. The ion implanter may include an ion source to generate an ion beam, and a linear accelerator, downstream to the ion source. The linear accelerator may include a buncher system to receive the ion beam and output a bunched ion beam, and a plurality of acceleration stages, to accelerate the bunched ion beam. The buncher system may include at least one RF buncher, a controller to adjust at least one control parameter of the at least one RF buncher over a plurality of instances; and a beam monitor, disposed downstream of the at least one RF buncher, and arranged to perform a plurality of beam measurements of the bunched ion beam over the plurality of instances. As such, the controller may be further arranged to determine a focal length of the buncher based upon the plurality of beam measurements.

### FIELD OF THE DISCLOSURE

The disclosure relates generally to ion implantation apparatus and more particularly to high energy beamline ion implanters.

### BACKGROUND OF THE DISCLOSURE

Ion implantation is a process of introducing dopants or impurities into a substrate via ion bombardment. Ion implantation systems may comprise an ion source and a series of beam-line components. The ion source may comprise a chamber where ions are generated. The ion source may also comprise a power source and an extraction electrode assembly disposed adjacent the chamber. The beam-line components, may include, for example, a mass analyzer, a first acceleration or deceleration stage, a collimator, and a second acceleration or deceleration stage. Much like a series of optical lenses for manipulating a light beam, the beam-line components can filter, focus, and manipulate ions or ion beam having particular species, shape, energy, and/or other qualities. The ion beam passes through the beam-line components and may be directed toward a substrate mounted on a platen or clamp.

Implantation apparatus capable of generating ion energies of approximately 500 keV or greater are often referred to as high energy ion implanters, or high energy ion implantation systems. One type of high energy ion implanter apparatus is termed a linear accelerator, or LINAC, where a series of electrodes arranged as tubes conduct and accelerate the ion beam to increasingly higher energy along the succession of drift tubes, where the electrodes receive an RF voltage signal that generates an accelerating electric field. Known LINACs are driven by an RF voltage applied at frequencies in the MHZ range, such as between 13.56 MHz-120 MHz.

In known LINACs (for the purposes of brevity, the term LINAC as used herein may refer to an RF LINAC using RF signals to accelerate an ion beam) in order to reach a targeted final energy, such as one MeV, several MeV, or greater, the ion beam may be accelerated in multiple acceleration stages. Each successive stage of the LINAC may receive the ion beam at increasingly higher energy, and accelerate the ion beam to still higher energy.

One component of a LINAC that is located upstream of the acceleration stages is generally termed a buncher. The buncher receives an ion beam as a continuous ion beam and performs a bunching operation to output the ion beam as a bunched ion beam, characterized by discrete bunches or packets of ions that are separated from one another in space and time.

Bunching of an ion beam is accomplished by modulating the energy and therefore the velocity of a continuous (DC) ion beam that is injected into the buncher. The modulation takes place by applying an RF voltage that generates an RF electric field that oscillates in a sinusoidal or other periodic fashion across the gaps between a set of drift tube electrodes. As a continuous stream of ions traverse the gap of a buncher, ions that arrive at a first instance when the field strength across the gap is relatively higher will accelerate to a greater extent and will achieve a higher velocity, while ions traversing at a second instance when the field strength is relatively lower will accelerate to a lesser extent, and will a achieve a relatively lower velocity. In this manner, a group of continuous ions traversing the buncher may be packetized into a series of bunches, after exiting the buncher, having a spacing in time that is defined by the RF frequency.

A synchronous ion within an ion bunch may be defined as an ion that traverses the entire buncher without undergoing any energy modulation. How tightly the ions of an ion bunch are distributed longitudinally about the synchronous ion may be characterized by a bunch length or bunch phase density, measured in degrees. For comparison, the DC (continuous) ion beam injected into the buncher can be treated as having a bunch length of 360 degrees, which bunch length is then compressed into ion bunches having a bunch length on the order of a couple of degrees. The bunch length of a bunched ion beam then presents a suitable tuning parameter that is to be managed to ensure efficient operation of the accelerating stages of the LINAC that accelerate the bunched ion beam. In particular, the LINAC acceleration stages may be characterized by a certain phase acceptance, an acceptance angle, representing an angular spread that can efficiently accelerate an incoming bunch. Moreover, the bunch length of bunches output by the buncher ideally should be equal or less than the phase acceptance of the LINAC.

With respect to these and other considerations, the present disclosure is provided.

### BRIEF SUMMARY

In one embodiment, an ion implanter is provided. The ion implanter may include an ion source to generate an ion beam, and a linear accelerator, downstream to the ion source. The linear accelerator may include a buncher system to receive the ion beam and output a bunched ion beam, and a plurality of acceleration stages, to accelerate the bunched ion beam. The buncher system may include at least one RF buncher, a controller to adjust at least one control parameter of the at least one RF buncher over a plurality of instances; and a beam monitor, disposed downstream of the at least one RF buncher, and arranged to perform a plurality of beam measurements of the bunched ion beam over the plurality of instances. As such, the controller may be further arranged to determine a focal length of the buncher based upon the plurality of beam measurements.

In a further embodiment, a method of operating an ion implanter is provided. The method may include generating a continuous ion beam, bunching the continuous ion beam to form a bunched ion beam, and varying a bunch length of the bunched ion beam at a plurality of instances. The method may further include measuring a characteristic of the bunched ion beam indicative of the bunch length, for the plurality of instances, and feeding back a signal indicative of the bunch length, so as to minimize the bunch length of the bunched ion beam when entering a first acceleration stage of the ion implanter.

In another embodiment, an ion implanter is provided. The ion implanter may include an ion source to generate an ion beam; and a linear accelerator, downstream to the ion source, where the linear accelerator includes a buncher system to receive the ion beam and output a bunched ion beam, and a plurality of acceleration stages, to accelerate the bunched ion beam. The buncher system may include a pair of RF bunchers, a controller to adjust at least one control parameter of the pair of RF bunchers over a plurality of instances, and a beam monitor, disposed downstream of the pair of RF bunchers and upstream of the plurality of acceleration stages. As such, the beam monitor may be arranged to perform a plurality of beam measurements of the bunched ion beam over the plurality of instances, where the controller is further arranged to determine a focal length of the buncher based upon the plurality of beam measurements.

### BRIEF DESCRIPTION OF THE DRAWINGS

FIG. 1A depicts a schematic of an ion implanter apparatus, according to embodiments of the disclosure;

FIG. 1B depicts details of an exemplary buncher;

FIG. 1C shows an exemplary controller;

FIG. 1D depicts a schematic of another ion implanter apparatus, according to embodiments of the disclosure;

FIG. 2 shows a buncher tuning arrangement, according to embodiments of the disclosure;

FIG. 3A depicts one embodiment of a beam monitor;

FIG. 3B depicts an example output of the beam monitor of FIG. 3A;

FIG. 3C presents a depiction of bunch length as a function of position along a beamline;

FIG. 4A depicts another embodiment of a beam monitor;

FIG. 4B depicts an example output of the beam monitor of FIG. 4A;

FIG. 5A depicts one set of experimental data using a buncher tuning system according to some embodiments;

FIG. 5B depicts another set of experimental data using a buncher tuning system according to other embodiments;

FIG. 6 depicts a further set of experimental data using a buncher tuning system according to additional embodiments;

FIG. 7 presents an exemplary process flow, in accordance with embodiments of the disclosure;

FIG. 8 presents another exemplary process flow, in accordance with embodiments of the disclosure;

FIG. 9 presents a further process flow, in accordance with embodiments of the disclosure; and

FIG. 10 presents another process flow, according to other embodiments of the disclosure.

The drawings are not necessarily to scale. The drawings are merely representations, not intended to portray specific parameters of the disclosure. The drawings are intended to depict exemplary embodiments of the disclosure, and therefore are not be considered as limiting in scope. In the drawings, like numbering represents like elements.

### DETAILED DESCRIPTION

An apparatus, system and method in accordance with the present disclosure will now be described more fully hereinafter with reference to the accompanying drawings, where embodiments of the system and method are shown. The system and method may be embodied in many different forms and are not be construed as being limited to the embodiments set forth herein. Instead, these embodiments are provided so this disclosure will be thorough and complete, and will fully convey the scope of the system and method to those skilled in the art.

Terms such as “top,” “bottom,” “upper,” “lower,” “vertical,” “horizontal,” “lateral,” and “longitudinal” may be used herein to describe the relative placement and orientation of these components and their constituent parts, with respect to the geometry and orientation of a component of a semiconductor manufacturing device as appearing in the figures. The terminology may include the words specifically mentioned, derivatives thereof, and words of similar import.

As used herein, an element or operation recited in the singular and proceeded with the word “a” or “an” are understood as potentially including plural elements or operations as well. Furthermore, references to “one embodiment” of the present disclosure are not intended to be interpreted as precluding the existence of additional embodiments also incorporating the recited features.

Provided herein are approaches for improved operation of high energy ion implantation systems and components, based upon a beamline architecture, and in particular, ion implanters based upon linear accelerators. For brevity, an ion implantation system may also be referred to herein as an “ion implanter.” Various embodiments provide architecture and tuning approaches for bunchers of RF linear accelerators (LINACs).

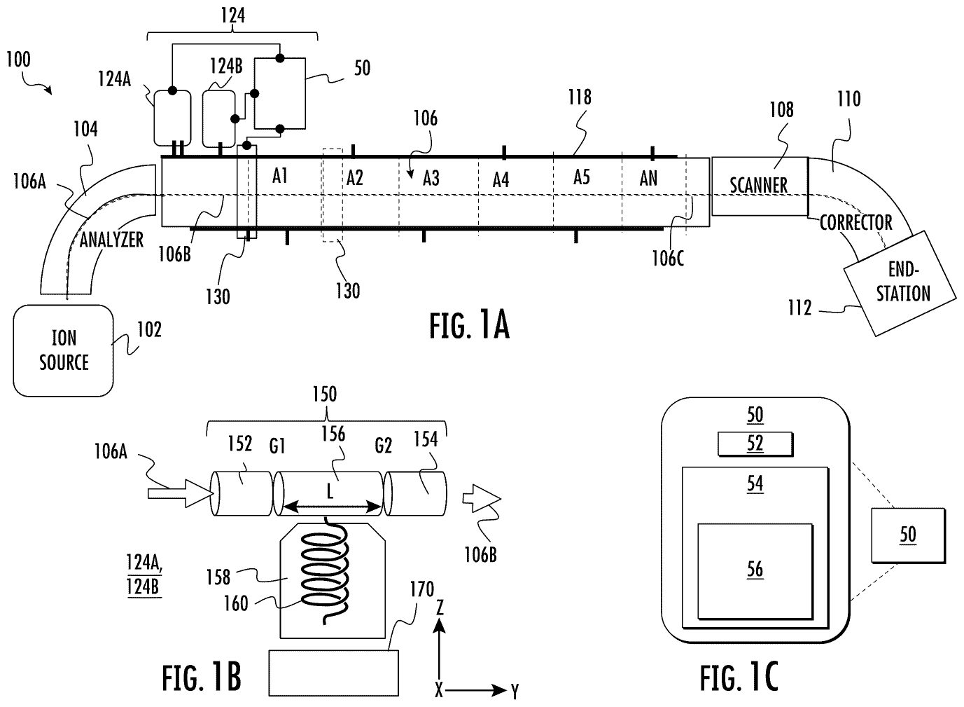

FIG. 1A depicts a schematic of an ion implanter apparatus, according to embodiments of the disclosure. The ion implanter 100 includes a linear accelerator, referred to herein as LINAC 118. The ion implanter 100, may represent a beamline ion implanter, with some elements not shown for clarity of explanation. The ion implanter 100 may include an ion source 102, as known in the art. The ion source 102 may include an extraction system including extraction components and filters (not shown) to generate an ion beam 106A at a first energy. As output by the ion source 102, the ion beam 106A may be a continuous ion beam. Examples of suitable ion energy for the first ion energy range from 5 keV to 300 keV, while the embodiments are not limited in this context. To form a high energy ion beam, the ion implanter 100 may include various additional components for accelerating the ion beam 106.

The ion implanter 100 may include an analyzer 104, functioning to analyze the ion beam 106 as in known apparatus, by changing the trajectory of the ion beam 106, as shown. The ion implanter 100 may also include a buncher system 124, which component may form an upstream part of an RF linear accelerator, shown as LINAC 118. The buncher system 124 may be arranged as in known apparatus to output the initially-continuous ion beam, meaning ion beam 106A, as a bunched ion beam 106B. The LINAC 118 may include various acceleration stages to accelerate the bunched ion beam 106B by application of an RF signal at the different stages. The LINAC may output the bunched ion beam 106B as a high energy ion beam 106C. The ion implanter 100 may include various additional components, such as a scanner 108, to scan the high energy ion beam 106C, such as in a transverse direction to a direction of propagation of the high energy ion beam 106C. The ion implanter may further include components such as a corrector 110 and end station 112, as known in the art.

To impart a target final energy to the high energy ion beam 106C, the LINAC 118 may include a series of RF assemblies, where a given RF assembly is arranged to deliver a given RF signal to a given acceleration stage of the LINAC 118. These RF assemblies are shown as assembly 122A, assembly 122B, assembly 122C, assembly 122D, assembly 122E, and assembly 122N. The RF signal generated by a given assembly serves to generate an accelerating RF electric field between electrodes that are contained in a given acceleration stage, as detailed with respect to FIG. 1B. The final energy imparted into the bunched ion beam 106B will depend upon the amplitude of the RF signals applied at each acceleration stage of the LINAC 118, the total number of acceleration stages, as well as the timing of the RF signals as applied to the different acceleration stages as the bunched ion beam 106B is conducted therethrough.

In various embodiments of the disclosure, the buncher system 124 may include at least one RF buncher, which buncher may be arranged to receive the ion beam 106A and output the bunched ion beam 106B. In the example of FIG. 1A, the buncher system 124 is depicted as having a pair of RF bunchers, including an RF buncher 124A and an RF buncher 124B, an upstream-most acceleration stage, shown as acceleration stage A1, an acceleration stage A2, an acceleration stage A3, an acceleration stage A4, acceleration stage A5, and acceleration stage AN, where AN may represent a downstream-most acceleration stage, with N representing any suitable number. Thus, while 6 acceleration stages are explicitly depicted in FIG. 1A, in various embodiments, a linear accelerator may include fewer or a larger number of acceleration stages. As the bunched ion beam 106B passes through successive acceleration stages of the LINAC 118, the bunched ion beam 106B will be accelerated to a high energy based upon the number of acceleration stages and the amplitude of the RF signal applied at each acceleration stage, among other factors, as noted above.

FIG. 1B depicts general features of an RF buncher according to embodiments of the disclosure. As in known bunchers, the RF buncher 124A and RF buncher 124B may be arranged with a series of drift tube electrodes whose arrangement is designed to bunch the continuous ion beam, that is, ion beam 106A. As an example, a first grounded drift tube 152, a powered drift tube 156, and a second grounded drift tube 154 may be provided, in sequence, as shown in FIG. 1B. An RF supply 170 is arranged to deliver power to a resonator 158, including a resonator coil 160 that is coupled to deliver an RF voltage signal to the powered drift tube 156. The potential of the powered drift tube 156 will thus vary in an oscillating fashion, such as a sinusoidal variation, with a period that is defined according to the frequency of the RF signal delivered from the resonator coil 160. A set of oscillating electric fields, will then develop between the powered drift tube 156 and the first grounded drift tube 152 and powered drift tube 156, and between the powered drift tube 156 and second grounded drift tube 154. This set of electric fields will develop across the gap G1 and the Gap G2 in particular, so that an ion traversing these gaps will experience an electric field along the Z-axis of the Cartesian coordinate system shown. Note that the local direction of propagation of ions of the ion beam 106 in the RF buncher 124A or RF buncher 124B will be generally along the Z-axis.

The magnitude and direction of the electric field experienced by the ion will depend upon the value and sign of the voltage signal at the powered electrode at the interval when the ion passes through the gap G1 or G2. Thus, positive ions entering into the gap G1 at an instance where the voltage signal at the powered drift tube 156 has a maximum negative amplitude, will experience a maximum acceleration across the gap G1, increasing in velocity and energy. Positive ions entering into the gap G1 at the instance where the voltage signal has a positive potential at powered drift tube 156, will experience a deceleration, reducing velocity and energy. The same phenomenon applies across gap G2. Thus, depending upon the timing of the arrival of individual ions at these gaps, the ions may be accelerated to a lesser or greater extent, or decelerated, leading to the formation of ion bunches. Ideally, the output of an RF buncher 124A or RF buncher 124B may be a series of ion bunches that have minimal phase length, such as just a few degrees, as noted above.

In the particular embodiment of FIG. 1B, the RF buncher 124A or RF buncher 124B are depicted as having a ‘double gap’ configuration with just one powered drift tube. However, in other embodiments, these RF bunchers may have a triple gap architecture, based upon two powered drift tubes. In the embodiment of FIG. 1A, the RF buncher 124A may be driven at a first frequency, while the RF buncher 124B is drive at a second frequency, which second frequency may differ from the first frequency. For example, the first frequency may be 13.56 MHz while the second frequency may be 27.12 MHz, in one non-limiting embodiment.

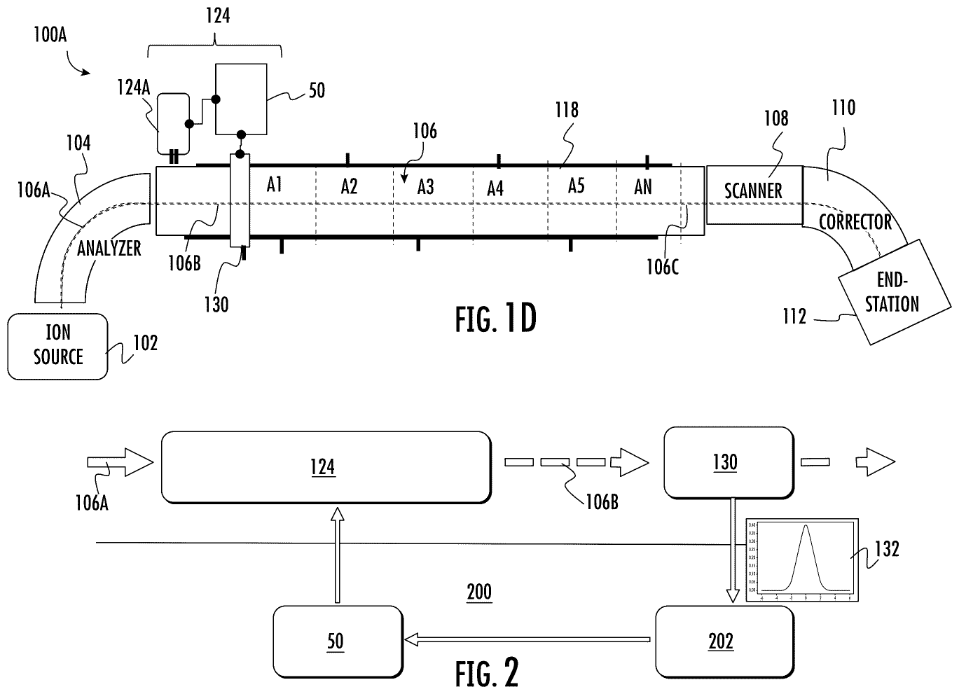

When the bunched ion beam 106B is output by the buncher system 124, the bunched ion beam 106B may be characterized as a series of ion bunches, having certain characteristics, including a bunch length, described previously. According to embodiments of the disclosure, the buncher system 124 may be provided with additional components to measure and control these certain characteristics, including the bunch length of the bunched ion beam 106B. As depicted in FIG. 1A, the buncher system 124 may include a beam monitor 130, disposed downstream of the RF buncher 124A and RF buncher 12B. The beam monitor 130 is arranged to perform a beam measurement of the bunched ion beam 106B, as described in particular with respect to FIGS. 2-6 to follow. The buncher system 124 may further include a controller 50 that is arranged to adjust at least one control parameter of the at RF bunchers of the buncher system 124, based upon the beam measurement. Details of the controller 50 are provided in FIG. 1C, with the operation described further below.

FIG. 2 shows a schematic block diagram depiction buncher tuning arrangement 200, according to embodiments of the disclosure. The buncher system 124 is arranged to output the ion beam 106A, initially continuous, as a bunched ion beam 106B, as described previously. The beam monitor 130 is disposed downstream of the buncher system 124, to measure the bunched ion beam 106B. Referring again to FIG. 1A, in some embodiments, the beam monitor 130 may be disposed downstream of the buncher system 124, while upstream of the acceleration stage A1. In other embodiments the beam monitor 130 may be disposed downstream of the acceleration stage A1, as indicated by the dashed outline in FIG. 1A. As the bunched ion beam 106B passes through the beam monitor 130, the beam monitor may perform sensing of the bunched ion beam 106B, and may output signals and/or data that characterizes the bunched ion beam. In particular embodiments, the beam monitor 130 may act as a bunch length detector to provide output for characterizing the bunch length of the bunched ion beam 106B.

In some embodiments, a presentation device 202 may be coupled to receive output from the beam monitor 130, and may include a visual interface, such as an oscilloscope or similar electronic device. In some embodiments, the presentation device 202 may record and/or output information 132 detected from the bunched ion beam 106B to the controller 50. In some examples, the controller 50 may analyze the information from the beam monitor 130, to determine, for example, a bunch length of the bunched ion beam 106B. The controller 50 may then output control signals to adjust operation of the buncher system as needed, depending upon the determined bunch length.

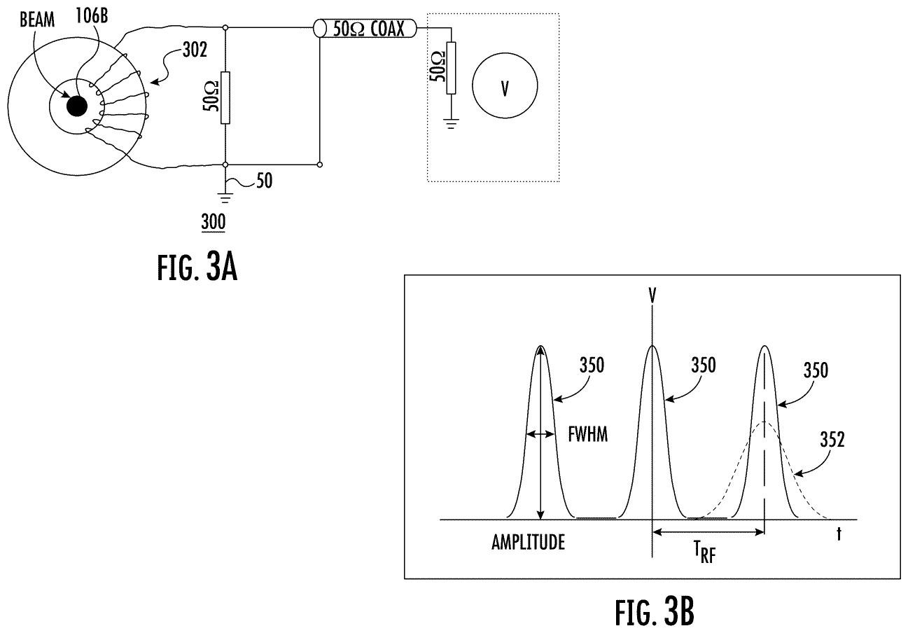

FIG. 3A depicts one embodiment of a beam monitor 300. In this example, the beam monitor 300 is an inductive beam monitor, including an inductive pickup 302, arranged in toroidal fashion to surround the bunched ion beam 106B, as the bunched ion beam traverses through the space within the inductive pickup 302. In operation, the beam monitor 300 is arranged to pick up the electromagnetic field generated by the bunched ion beam 106B, which field may generate a Gaussian-like shaped signal proportional to the characteristics of each ion bunch of the bunched ion beam 106B. The theory of operation of the beam monitor 300 may be compared to a transformer, where the primary coil of the transformer is represented by an ion bunch of the bunched ion beam 106B, and the secondary winding of the transformer is the beam monitor 300 itself. In particular, as an ion bunch of the bunched ion beam 106B travels through the beam monitor 300, the ion bunch induces a voltage on the windings in the beam monitor 300, which windings may be wrapped around a torus support structure as shown, to enhance the signal integrity. Certain assembly characteristics for the beam monitor 300 may enhance operation of the beam monitor, including isolation from wall currents, as well as a short rise time for signal detection. Moreover, to ensure proper measurement resolution, the length of the beam monitor along the direction of propagation of a bunch should be shorter than the bunch length. In some embodiments the beam monitor 300 may be positioned close to the first RF acceleration stage, meaning stage A1, as shown in FIG. 1A, and discussed further below. As noted above with respect to FIG. 2, the induced voltage signal detected by the beam monitor 300 may be output to an external device, such as an oscilloscope, for analysis of some characteristics of the signal. Such analysis may be based upon:
a) FWHM—the full width half max (or simply “half-width”) is indicative of the bunch length of an ion bunch. The bigger the FWHM, the longer the bunch. Therefore, to ensure minimum bunch length at the beam monitor 300, according to some embodiments, the buncher system suitable controls for the buncher system 124 may be adjusted, in order to minimize the FWHM detected at the beam monitor 300.
b) Amplitude—the amplitude of the voltage signal may also be used to determine the bunch length. The higher the voltage induced at a given instance by a passing ion bunch of the bunched ion beam 106B, the higher the charge density in the ion bunch at that instance. The higher the charge density over time, the shorter the ion bunch. Thus, a highest amplitude of the voltage signal may indicate a minimum bunch length.

Thus, in various embodiments, the controller 50, either automatically, or with user input, may adjust control signals for a control parameter that is used to control at least one buncher of a buncher system, in order to adjust the half-width or the amplitude of a voltage signal received at the beam monitor 300, to reach a maximum of minimum value. In some examples, a control parameter sweep may be performed to determine a value of a given control parameter of the buncher system that generates a minimum half-width or maximum amplitude, as discussed further below.

To illustrate this point further, FIG. 3B depicts an example output of the beam monitor 300 of FIG. 3A. In this example, a graph is provided depicting a voltage pulse train, characterized by a series (in this case, three) of voltage pulses or voltage peaks that are generated by a series of ion bunches passing through the beam monitor 300. The abscissa represents time, while the ordinate axis represents amplitude of the voltage. The characteristic parameters of the voltage pulses 350 are shown, including half-width (FWHM) and amplitude. For a given voltage pulse, a relatively shorter ion bunch will generate a relatively smaller half-width and a relatively larger amplitude. Conversely, a relatively longer ion bunch will generate a relatively larger half-width and a relatively smaller amplitude, as suggested by the voltage pulse 352. Thus, in the example of FIG. 3B, the controller 50 may operate to adjust controls for the buncher system 124 to adjust the characteristics of a voltage pulse from voltage pulse 352 to the voltage pulse 350.

A goal of this approach is to provide the ability to minimize the bunch length or phase density, or at least determine the parameters that set the bunch length at a minimum. In so doing, by determining the parameters that set the bunch length at a minimum at the beam monitor 300, the position where bunch length reaches a minimum along a beamline may be adjusted, with respect to the beam monitor, to locate the position of minimum bunch length or phase angle at a suitable beamline location, such as, at the first acceleration stage. To emphasize this point, FIG. 3C presents a depiction of bunch length in terms of phase, as a function of position along a beamline. In this scenario, a continuous ion beam, ion beam 106A, enters a buncher system 124, and propagates along the horizontal direction. The vertical axis represents bunch length in terms of phase, where 360 degrees represent a continuous ion beam. After exiting the buncher system 124, a bunched beam, not separately shown, will become longitudinally focused at a focal point 360, where the bunch length is a minimum, where the phase may be just several degrees. This focusing takes place because ions arriving at different instance into the acceleration gaps of the buncher will be accelerated or decelerated according to arrival time, leading to a longitudinal convergence at the focal point 360. Assuming that the buncher system 124 is tuned to generate a minimum bunch length at the position of the beam monitor 130, then, with knowledge of the relative position of the acceleration stage A1 with respect to beam monitor 130, suitable adjustments to the control parameters of the buncher system 124 to move the longitudinal focal point to the position of A1, if desired.

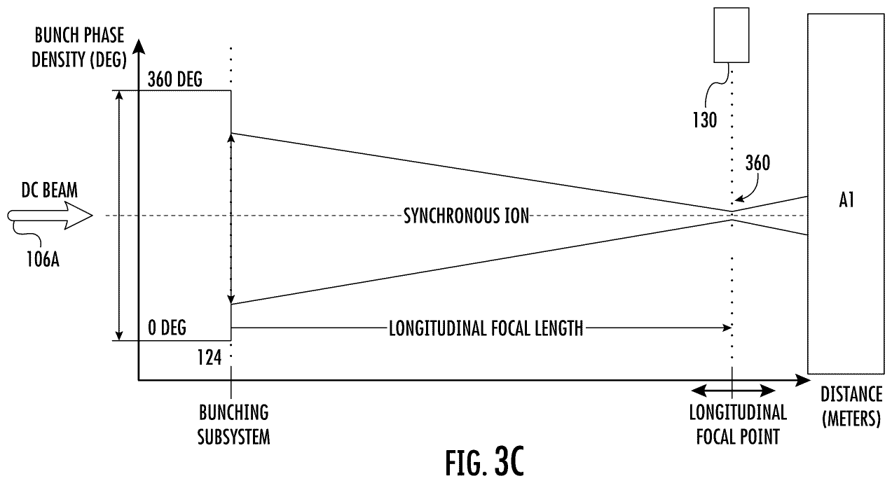

FIG. 4A depicts another embodiment of a beam monitor 400, in this case, a capacitive beam monitor. The beam monitor 400 may include an electrode 402, arranged within a beamline enclosure 404, which enclosure is part of the enclosure of the bunchers and the acceleration stages of a linear accelerator that enclose the ion beam 106. The electrode 402 is an electrically isolated pickup electrode that wraps around the beam axis of the bunched ion beam 106B in a donut shaped fashion. In operation, the beam monitor 440 picks up the image currents generated by the ion bunches of the bunched ion beam 106B, which currents may generate a 1^{st} order Gaussian derivative signal depending on the characteristics of the ion bunch. As an ion bunch of the bunched ion beam 106B travels through the beam monitor 400, the electric field of the bunched ion beam 106B couples to the pickup electrode (electrode 402) and generates corresponding image currents. The change in current observed on the electrode 402 is then measured across a resistor 406 as a voltage signal. This voltage signal may then be fed to an external device for analysis, such as to an oscilloscope, or controller, or a combination of the two. The analysis may be based upon suitable characteristics of the voltage signal.

FIG. 4B depicts an example output of the beam monitor of FIG. 4A. This output is provided in FIG. 4B as a graph that represents the aforementioned voltage signal, where time is represented on the abscissa, and voltage on the ordinate. In FIG. 4B, a curve 450 and a curve 452 are depicted, representing derivative signals, as described above, such as a so-called 1^{st} order Gaussian derivative signal. A given ion bunch passing through the beam monitor 400 will generate a derivative signal characterized by a peak pair formed by a ‘positive’ peak and a ‘negative peak’ as shown. Thus, the curve 450 and the curve 452 represent the signals generated by the passage of two ion bunches through the beam monitor 400.

In one embodiment, the bunch length of ion bunches may be analyzed and adjusted according to a characteristic slope of the curve 450 or curve 452, such as a so called ‘80-20’ slope. The 80-20 slope is represented by the slope between points A and B for curve 450, where point B may represent the point that is 20% of the distance between the lowest voltage point on the curve 450 and highest voltage point on the curve 450, while the point A represents the point that is 80% of the distance between the lowest voltage point on the curve 450 and highest voltage point on the curve 450. In curve 452, the 80-20 points are indicated by A′ and B′. The steeper the 80-20 slope, the faster the beam-induced image currents change over time, indicating a tighter distribution of ions in a passing ion bunch. Thus, the curve 450 indicates a series of ion bunches having a relatively shorter bunch length as compared to the ion bunches generating the curve 452.

Note that for proper measurement to be conducted, the beam monitor length is to be smaller than the bunch length of an ion bunch, to produce the required resolution when tuning the buncher system 124. Further note that, in some embodiments, the bunch length may be determined from the curve 450 or curve 452 by determining the total width of the derivative signal, as indicated by the distance between points C and D for curve 450. Said differently, theoretically, the absolute bunch length is approximately the separation between point C and D. However this measurement is more susceptible to uncertainties in measurement, in comparison to measuring the falling slope (80-20 slope) between point A and B. Accordingly, tuning a buncher to generate a shortest bunch length may be accomplished by maximizing the 80-20 slope between point A and B for signals generated by passing ion bunches.

In various embodiments, suitable control parameters for tuning buncher systems may depend upon the configuration of a buncher system. In accordance with various embodiments of the disclosure, a buncher system may be based upon two RF bunchers as discussed above with respect to FIG. 1A. In this circumstance, one suitable control parameter is the phase offset between RF signals applied to a first buncher and a second buncher in a buncher system.

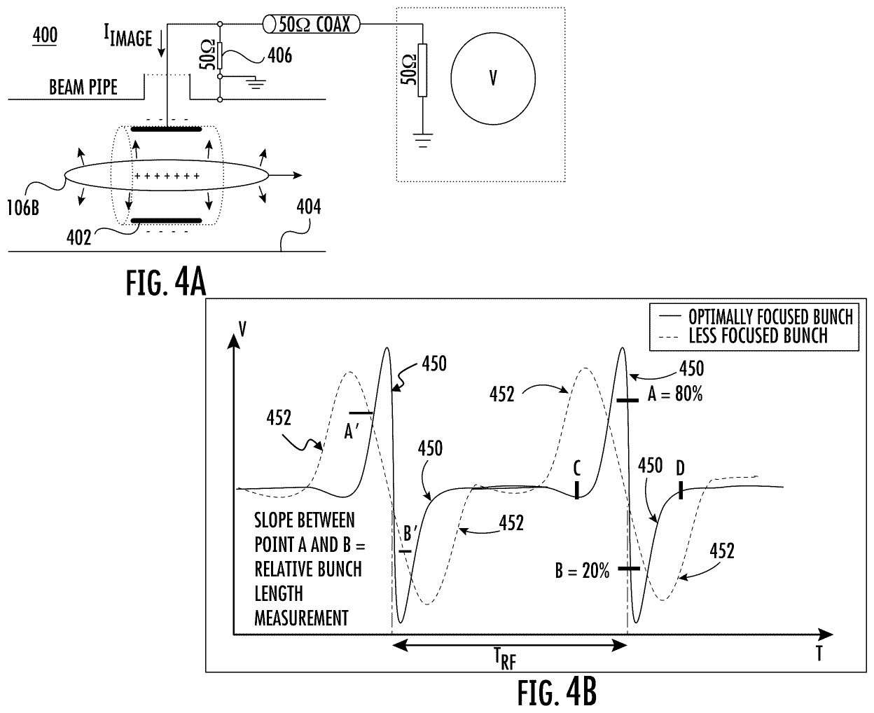

FIG. 5A depicts one set of experimental data using a buncher tuning system according to some embodiments. In FIG. 5A, there is a graph depicting the measured pulse width of a voltage pulse from an inductive beam monitor as a function of phase offset between a first RF signal sent to a first buncher and a second RF signal sent to a second buncher. Curve 500 connects measured data points measured at a series of phase offset angles from 0 degrees to 400 degrees.

FIG. 5B depicts another set of experimental data using a buncher tuning system according to other embodiments. In this case, the graph of FIG. 5B depicts measured pulse amplitude (RMS voltage) from an inductive beam monitor as a function of phase offset between a first RF signal sent to a first buncher and a second RF signal sent to a second buncher. In this case, the data of curve 520 of FIG. 5B may be collected from the same buncher measurements as the data in FIG. 5A.

Thus, the independent variable (control parameter) that is tuned in the example of FIGS. 5A and 5B is the phase angle (offset) between two RF bunchers, while the dependent variable (measurement parameter) is the pulse FWHM (half-width) in FIG. 5A and pulse amplitude in FIG. 5B. The data from both curve 500 and curve 510 indicate that the bunch length is minimized in a phase range 512, between approximately 375 degrees and 385 degrees phase offset. In other words, the peak amplitude of curve 500 is maximum in the phase range, while the half-width is minimum.

In various embodiments of the disclosure, an optimization routine for tuning a buncher system may be performed with each free variable, meaning a control parameter, of the buncher system. For a given ion implantation recipe that has a given injection ion energy (of the ion beam 106A entering the buncher system 124) and/or a given mass-to-charge ratio, the tuning of an ion implanter may entail a buncher tuning procedure for that given ion implantation recipe. Thus, changing an ion implantation recipe may call for employing a new buncher tuning procedure for the changed ion implantation recipe. This tuning of the buncher with changes in the ion implantation recipe is used to ensure the buncher system generates a proper bunch length at the given ion implantation recipe, so that the focal length of a buncher aligns with a first RF acceleration stage. For example, an increase in energy or atomic mass of the injected ion species will need increased bunching voltage to converge the ions into a bunch at the same focal length. Thus, in some examples, the power for driving a buncher may be increased to generate a resulting voltage amplitude increase of the RF voltage signal at the powered electrode of a buncher.

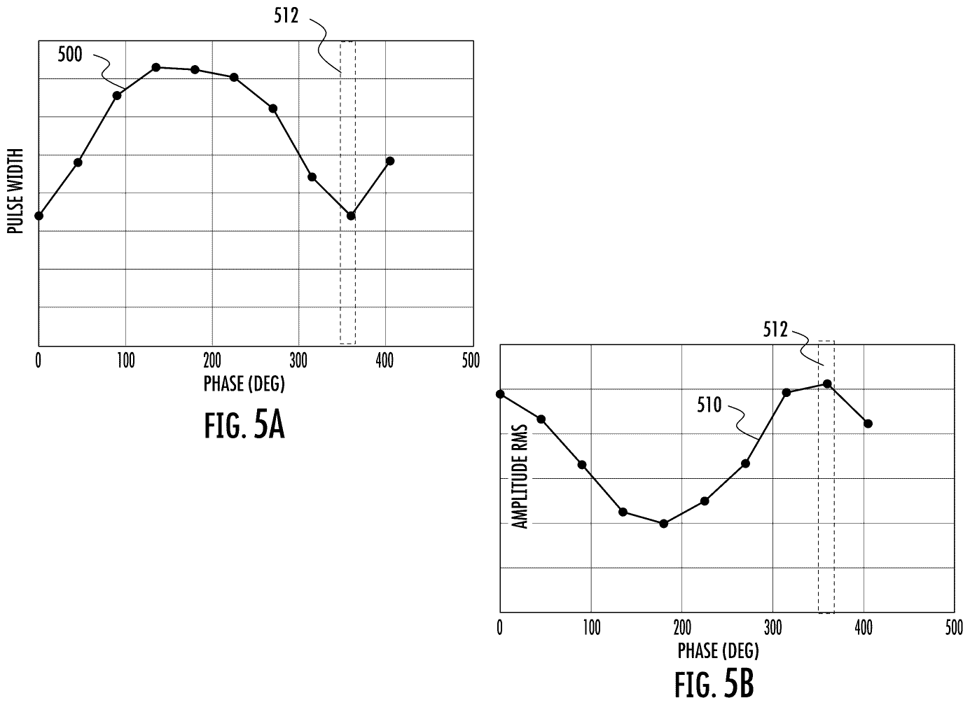

FIG. 6 depicts a further set of experimental data using a buncher tuning system according to additional embodiments. In FIG. 6, a graph is presented illustrating the pulse width of a voltage pulse detected at an inductive beam monitor, as a function of power delivered to an RF buncher. In this implementation, the RF buncher is a first buncher of a two-buncher system. The curve 600 is fitted to the data points taken through a power range of 200 W to 490 W. The pulse width reaches a minimum between approximately 305 W and 320 W, indicating a appropriate power range to achieve the narrowest bunching given the specific ion implantation recipe.

According to various embodiments of the disclosure, a beam monitor may be placed in close proximity to the drift tube assembly of the first acceleration stage of a linear accelerator, meaning the most upstream acceleration stage (see stage A1). Note that when a buncher system is tuned to minimize the buncher length at a beam monitor, as described above, this minimizing of buncher length of the RF buncher is set at the beam monitor position along the beamline of the ion implanter. More particularly, the focal length may be considered to be the distance from an RF buncher, in the downstream direction of the RF buncher, where an ion bunch achieves minimal bunch length, that is, the minimal dimension along the direction of propagation of the ion bunch. Thus, when the buncher system settings are such that the bunch length is minimized at a beam monitor, the bunched ion beam is longitudinally focused at the beam monitor.

With the above concept in mind, in some embodiments, the beam monitor may be located just upstream of the drift tube assembly of the first acceleration stage (see A1 of FIG. 1A). For example, the beam monitor may be located several centimeters or a few tens of centimeters upstream of the first drift tube of an acceleration stage. Note that the bunch length, such as in degrees, is to be set to be less than the phase acceptance (acceptance angle) of the first acceleration stage. In this scenario, in order to minimize the bunch length at the acceleration stage, rather than at the beam monitor, the settings of the buncher system may be adjusted to increase slightly the focal length of the RF buncher so that the focal length coincides with the position of the drift tube assembly of the first acceleration stage.

In other embodiments, the beam monitor may be placed just downstream of the first acceleration stage. In this latter scenario, given that tuning of the RF buncher to achieve minimum bunch length at the beam monitor means the focal length is located downstream of the acceleration stage, the RF buncher settings may then be slightly adjusted in an opposite manner to the case where the beam monitor is upstream of the first acceleration stage. Thus, in this latter scenario, the focal length for the buncher system will be reduced from the focal length determined for the position of the beam monitor, such that the reduced focal length corresponds to the position of the drift tubes in the first acceleration stage. Note that in the case where the beam monitor is located downstream to the first acceleration stage, the first acceleration stage will be turned off so that the beam monitor just measures the bunched ion beam as processed by the RF buncher. The acceleration stages of the linear accelerator may also generally be maintained OFF in the case where the beam monitor is located upstream of the first acceleration stage.

In various embodiments of the disclosure, where buncher tuning may be partially or fully automated, buncher tuning may be performed using a gradient descent algorithm. The cost function for this approach is rather simple, since for each architecture just one target parameter need be selected to descend upon. As noted above, the parameter of interest for use with an inductive beam monitor may be pulse width, and for the capacitive beam monitor the parameter may be the “80-20”slope.

Referring again to FIG. 1C, there are shown details of a controller 50, arranged to implement the procedures of the present embodiments as set forth above. In one embodiment, the controller 50 may include a processor 52, such as a known type of microprocessor, dedicated processor chip, general purpose processor chip, or similar device. The controller 50 may further include a memory or memory unit 54, coupled to the processor 52, where the memory unit 54 contains a buncher tuning routine 56. The buncher tuning routine 56 may be operative on the processor 52 to control the ion implanter 100, and in particular to aid in establishing the proper control settings at a buncher system, such as the buncher system 124.

In particular, the buncher tuning routine 56 may be operative on the processor 52 to control the ion implanter 100 to generate a bunched ion beam by applying a set of control parameters to at least one RF buncher in a buncher system of the ion implanter 100. The buncher tuning routine 56 may further be operative to receive a beam measurement of a bunched ion beam from a beam monitor of the buncher system, and to adjust at least one control parameter of the set of control parameters, based upon the beam measurement. Among these control parameters may be the phase offset between bunchers of a dual RF buncher system, RF power delivered to a buncher, or voltage amplitude delivered to the powered buncher electrode. In some embodiments, the control parameter(s). In some embodiments, the adjustment of the control parameters of an RF buncher may be based upon a particular measurement parameter received from the beam monitor, such as half-width, in the case of an inductive beam monitor, or “80-20” slope of a derivative voltage signal in the case of a capacitive beam monitor.

In some embodiments, the different control parameters may be adjusted in an iterative and cooperative manner among the different control parameters to minimize buncher length, for example. In one particular instance, a phase sweep may be performed between the relative phase of signals sent to two different bunchers, to determine an initial suitable phase offset value between bunchers. This phase sweep may be followed by a power sweep of a first buncher at the initial phase offset value, followed by a power sweep of the second buncher at the initial suitable phase offset value. These two power sweeps may be used to determine initial suitable power values for driving each buncher. A second narrower phase sweep, near the initial suitable phase offset value may then be employed when the two bunchers are set to the respective initial suitable power values. This iterative process may be continued to an extend where the bunch length is no longer shortened with further adjustments to phase offset between bunchers or power applied to the bunchers.

The memory unit 54 may comprise an article of manufacture. In one embodiment, the memory unit 54 may comprise any non-transitory computer readable medium or machine readable medium, such as an optical, magnetic or semiconductor storage. The storage medium may store various types of computer executable instructions to implement one or more of logic flows described herein. Examples of a computer readable or machine-readable storage medium may include any tangible media capable of storing electronic data, including volatile memory or non-volatile memory, removable or non-removable memory, erasable or non-erasable memory, writeable or re-writeable memory, and so forth. Examples of computer executable instructions may include any suitable type of code, such as source code, compiled code, interpreted code, executable code, static code, dynamic code, object-oriented code, visual code, and the like. The embodiments are not limited in this context.

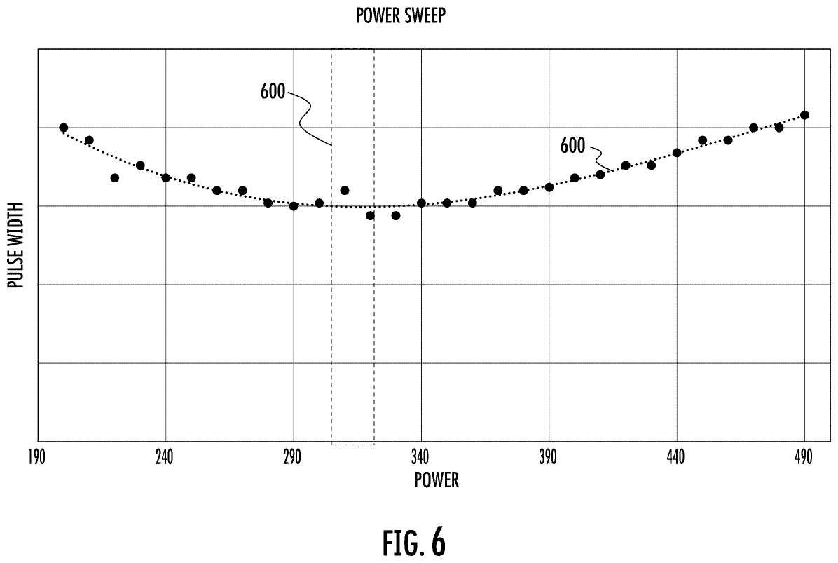

FIG. 7 presents an exemplary process flow 700, in accordance with embodiments of the disclosure. At block 702, a bunched ion beam is generated in a buncher system of an ion implanter. The bunched ion beam may be generated based upon a current set of control parameters of the buncher system, such as voltage amplitude, power, or phase offset between RF bunchers, in the case of a dual buncher system.

At block 704, a beam measurement is received form a beam monitor that is located downstream to the buncher system. For example, the beam monitor may be located just upstream of a first acceleration stage of an linear accelerator of the ion implanter, or alternatively may be located downstream to the first acceleration stage, such as between the first acceleration stage and a second acceleration stage. The beam measurement may be based upon an inductive beam monitor or a capacitive beam monitor according to some non-limiting embodiments.

At block 706, at least one control parameter of the set of control parameters may be adjusted in the buncher system.

At block 708, an updated beam measurement of the bunched ion beam is received form the beam monitor after adjusting of the at least one control parameter.

At decision block 710, a determination is made as to whether the current beam measurement indicates the ion bunches of the bunched ion beam have an acceptable bunch length. The indication of acceptable bunch length may be a predetermined phase angle maximum for the bunch length, or may be and indication that the bunch length is at a minimum bunch length. For example, a minimum bunch length may be determined when a value of a signal parameter from the beam measurement has reached a minimum or maximum value as a function of varying the control parameter. If so, the process ends. If not, the process returns to block 702, where further adjustment is performed. Thus, in one implementation, the exemplary process flow 700 may proceed until parameters are adjusted so that the bunch length reaches a minimum value such that further adjustments to control parameters result in increased bunch length. In other implementations, an acceptable bunch length as measured by the beam monitor need not be a minimum bunch length, but may lie near a minimum bunch length, such that the minimum bunch length may be predicted to occur at a position of a first acceleration stage, for example.

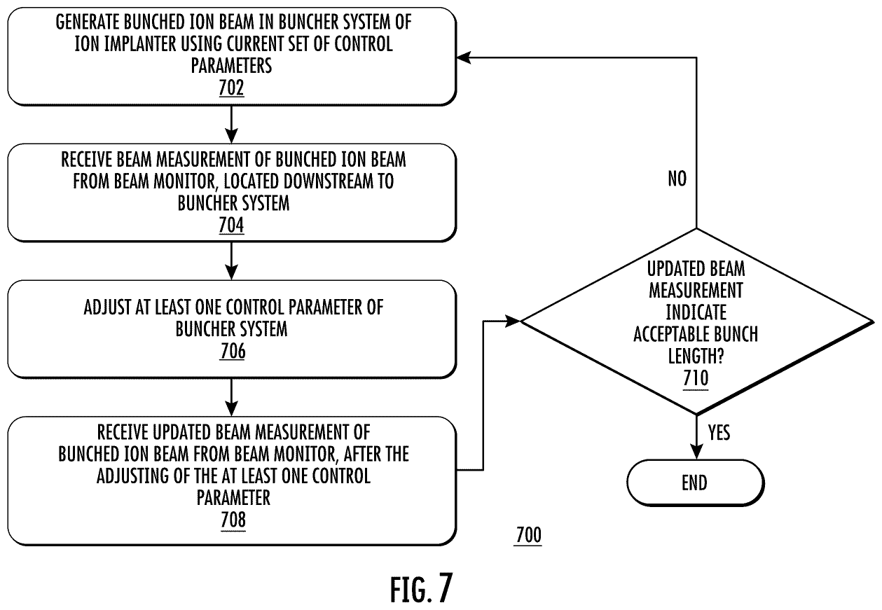

FIG. 8 presents another exemplary process flow 800, in accordance with embodiments of the disclosure. At block 802, a bunched ion beam is generated in a buncher system of an ion implanter based upon a set of control parameters. At block 804, at least one control parameter is adjusted at a plurality of measurement instances so that beam measurements may be made at the plurality of instances, where the control parameter has different values at each instance of the plurality of instances. Exemplary control parameters may be as described above with respect to FIG. 7.

At block 806, a plurality of beam measurements are received for the bunched ion beam from an inductive beam monitor located downstream of the buncher system, for the plurality of measurement instances.

At block 808, a half-width of a voltage pulse of a voltage signal generated by the beam measurements is determined for the plurality of beam measurements.

At block 810, a value of a control parameter is determined for generating a minimum bunch length based upon the half-width of the voltage pulses at the plurality of beam measurements.

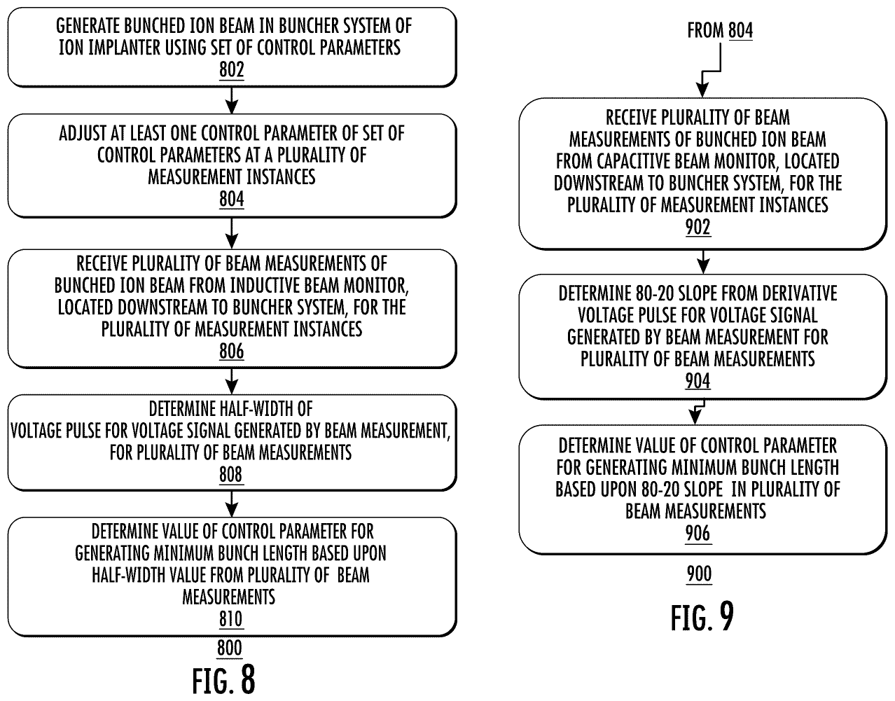

FIG. 9 presents a further process flow 900, in accordance with embodiments of the disclosure. The process begins from block 802 and block 804, described above with respect to FIG. 8. At block 902, a plurality of beam measurements are received for the bunched ion beam from a capacitive beam monitor located downstream of the buncher system, for the plurality of measurement instances, as described with respect to block 804. At block 904, an 80-20 slope is determined from a derivative voltage pulse for a voltage signal generated by a beam measurement, performed at the plurality of beam measurements. At block 906, a value of a control parameter is determined for generating a minimum bunch length based upon the 80-20 slope of the derivative voltage pulses at the plurality of beam measurements.

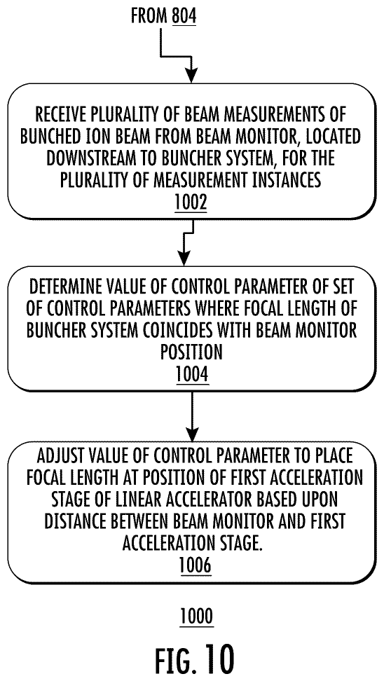

FIG. 10 presents a further process flow 1000, in accordance with embodiments of the disclosure. The process begins from block 802 and block 804, described above with respect to FIG. 8. At block 1002, a plurality of beam measurements are received of a bunched ion beam from a beam monitor, located downstream to the buncher system, for the plurality of measurement instances. At block 1004, a value of a control parameter of the set of control parameters is determined where the focal length of the buncher system coincides with the beam monitor position. At block 1006 a value of the control parameter is adjusted to place the focal length of the buncher system at the position of a first acceleration stage of the linear accelerator, based upon the distance between the beam monitor and the first acceleration stage.

In view of the above, the present disclosure provides at least the following advantages. The present embodiments provides you the ability to tune any buncher configuration (single, double, triple bunchers) for any input beam (Mass, Energy, Charge) to any accelerating stage architecture. Moreover, the tuning of the bunches is accomplished without the need to turn any acceleration stages on. Setting up of bunchers correctly according to the present embodiments provides a platform to then tune the acceleration stages and efficiently accelerate the bunches. This “piecewise” tuning of the LINAC simplifies and substantially speeds up the process. Thus, the present embodiments, by providing an automated routine for minimizing bunch length, and setting the proper focal length of buncher system, will routinely significantly reduce tune time when a new recipe is generated for an ion implanter, such as a new charge/mass ratio for ions, ion energy, and so forth. In another advantage, the present embodiments facilitate the ability to perform live metrology feedback during normal ion implanter operation due to the non-destructive nature of the buncher control routines as specified herein.

While certain embodiments of the disclosure have been described herein, the disclosure is not limited thereto, as the disclosure is as broad in scope as the art will allow and the specification may be read likewise. Therefore, the above description is not to be construed as limiting. Those skilled in the art will envision other modifications within the scope and spirit of the claims appended hereto.

1. An ion implanter, comprising:
an ion source to generate an ion beam; and
a linear accelerator, downstream to the ion source, the linear accelerator comprising:
a buncher system to receive the ion beam and output a bunched ion beam; and
a plurality of acceleration stages, to accelerate the bunched ion beam,
wherein the buncher system comprises:
at least one RF buncher;
a controller to adjust at least one control parameter of the at least one RF buncher over a plurality of instances; and
a beam monitor, disposed downstream of the at least one RF buncher, and arranged to perform a plurality of beam measurements of the bunched ion beam over the plurality of instances,
wherein the controller is further arranged to determine a focal length of the buncher based upon the plurality of beam measurements.

2. The ion implanter of claim 1, the at least one RF buncher comprising a pair of RF bunchers, wherein the beam monitor is disposed downstream to the pair of RF bunchers.

3. The ion implanter of claim 1, the beam monitor comprising an inductive beam monitor, or a capacitive beam monitor.

4. The ion implanter of claim 3, wherein the beam monitor is an inductive beam monitor, wherein the beam measurement comprises a voltage peak that is induced by the bunched ion beam, wherein the controller is arranged to adjust the at least one control parameter based upon a half-width of the voltage peak, an amplitude of the voltage peak, or a combination thereof.

5. The ion implanter of claim 3, wherein the beam monitor is a capacitive beam monitor, wherein the beam measurement comprises a voltage pulse train that is induced by the bunched ion beam, wherein the controller is arranged to adjust the at least one control parameter based upon a characteristic slope of a peak pair of the voltage pulse train.

6. The ion implanter of claim 2, wherein the at least one control parameter is a phase offset between a first RF buncher and a second RF buncher of the pair of RF bunchers.

7. The ion implanter of claim 1, the beam monitor comprising an inductive beam monitor, wherein the at least one control parameter is an amount of RF power that is delivered to the at least one RF buncher.

8. The ion implanter of claim 1, wherein the beam monitor is arranged upstream to the plurality of acceleration stages.

9. A method of operating an ion implanter, comprising:
generating a continuous ion beam;
bunching the continuous ion beam to form a bunched ion beam;
varying a bunch length of the bunched ion beam at a plurality of instances;
measuring a characteristic of the bunched ion beam indicative of the bunch length, for the plurality of instances; and
feeding back a signal indicative of the bunch length, so as to minimize the bunch length of the bunched ion beam when entering a first acceleration stage of the ion implanter.

10. The method of claim 9, wherein the bunching is performed by a pair of RF bunchers, and wherein the measuring is performed by a beam monitor, disposed downstream to the pair of RF bunchers.

11. The method of claim 10, wherein the beam monitor is an inductive beam monitor, wherein the measuring the characteristic of the bunched ion beam comprises receiving a voltage peak that is induced by the bunched ion beam when passing the inductive beam monitor, and wherein the characteristic comprises a half-width of the voltage peak, an amplitude of the voltage peak, or a combination thereof.

12. The method of claim 10, wherein the beam monitor is a capacitive beam monitor, wherein the measuring comprises receiving a voltage pulse train that is induced by the bunched ion beam, when passing the capacitive beam monitor, wherein the characteristic is a slope of a peak pair of the voltage pulse train.

13. The method of claim 10, wherein the bunch length is minimized by adjusting a phase offset between a first RF buncher and a second RF buncher of the pair of RF bunchers.

14. The method of claim 10, the beam monitor comprising an inductive beam monitor, wherein the bunch length in minimized by adjusting an amount of RF power that is delivered to the pair of RF bunchers.

15. The method of claim 9, wherein the bunch length is minimized by:
determining, a value of at least one control parameter of a buncher that bunches the continuous ion beam, where a bunch length of the bunched ion beam is a minimum at a beam monitor that measures the characteristic of the bunched ion beam; and
adjusting the value of the at least one control parameter based upon a distance between the beam monitor and the first acceleration stage.

16. An ion implanter, comprising:
an ion source to generate an ion beam; and
a linear accelerator, downstream to the ion source, the linear accelerator comprising:
a buncher system to receive the ion beam and output a bunched ion beam; and
a plurality of acceleration stages, to accelerate the bunched ion beam,
wherein the buncher system comprises:
a pair of RF bunchers;
a controller to adjust at least one control parameter of the pair of RF bunchers over a plurality of instances; and
a beam monitor, disposed downstream of the pair of RF bunchers and upstream of the plurality of acceleration stages, the beam monitor being arranged to perform a plurality of beam measurements of the bunched ion beam over the plurality of instances,
wherein the controller is further arranged to determine a focal length of the buncher system based upon the plurality of beam measurements.

17. The ion implanter of claim 16, the beam monitor comprising an inductive beam monitor, or a capacitive beam monitor.

18. The ion implanter of claim 17, wherein the beam monitor is an inductive beam monitor, wherein the plurality of beam measurements comprise a voltage peak that is induced by the bunched ion beam, wherein the controller is arranged to adjust the at least one control parameter based upon a half-width of the voltage peak, an amplitude of the voltage peak, or a combination thereof.

19. The ion implanter of claim 17, wherein the beam monitor is a capacitive beam monitor, wherein the beam measurement comprises a voltage pulse train that is induced by the bunched ion beam, wherein the controller is arranged to adjust the at least one control parameter based upon a characteristic slope of a peak pair of the voltage pulse train.

20. The ion implanter of claim 16, wherein the at least one control parameter comprises one or more of:
a phase offset between a first RF buncher and a second RF buncher of the pair of RF bunchers; and
an amount of RF power that is delivered to at least one RF buncher of the pair of RF bunchers.
